(19) United States
(12) Patent Application Publication
(10) Pub. No.: US 2012/0261772 A1
(43) Pub. Date: Oct. 18, 2012

(54) Semiconductor Device and Method for Manufacturing the Same

(76) Inventors: Haizhou Yin, Poughkeepsie, NY (US); Huilong Zhu, Poughkeepsie, NY (US); Zhijiong Luo, Poughkeepsie, NY (US)

(21) Appl. No.: 13/378,996

(22) PCT Filed: Aug. 9, 2011
(86) PCT No.: PCT/CN11/01314

§ 371 Date: Dec. 16, 2011

(30) Foreign Application Priority Data
Apr. 15, 2011 (CN) 201110094967.7

(51) Int. Cl. H01L 29/78; H01L 21/336

(52) U.S. Cl. 257/411; 438/287; 257/E29.255; 257/E21.409

(57) ABSTRACT

A semiconductor device comprises a gate stack, a source region, a drain region, a contact plug and an interlayer dielectric, the gate stack being formed on a substrate, the source region and the drain region being located on opposite sides of the gate stack and embedded in the substrate, the contact plug being embedded in the interlayer dielectric, wherein the contact plug comprises a first portion which is in contact with the source region and/or drain region, the upper surface of the first portion is flushed with the upper surface of the gate stack, and the angle between a sidewall and a bottom surface of the first portion is less than 90°. There is also provided a method for manufacturing a semiconductor device. Not only the contact area between the first portion and the source region and/or the drain region can be increased, which facilitates reducing the contact resistance; but also the distance between the top of the first portion and the top of the gate stack can be increased, which facilitates reducing the possibility of short circuit between the first portion and the gate stack.

### FIELD OF THE INVENTION

The invention relates to the field of manufacturing a semiconductor, particularly to a semiconductor device and a method for manufacturing the same.

### BACKGROUND OF THE INVENTION

A semiconductor device (e.g., transistor) comprising a source region and a drain region is an element commonly used in an integrated circuit. And a contact structure implementing a required electrical connection between the source region and the drain region of the semiconductor device and other components in the circuit is one of the important integral parts in the circuit.

An example of a prior contact structure is shown in FIG. 1. As shown in FIG. 1, the contact structure 130 is formed on the source region and drain region of a semiconductor device comprising a gate, a source region and a drain region. The top 131 of the contact structure is larger than its bottom 133.

However, such a contact structure has the following problems. Since the bottom of the contact structure is small, the contact area between the contact structure and the source region and the drain region is small, which will have a gradually increasing effect on the contact resistance as the size of the semiconductor device is gradually decreased. Furthermore, the distance between the top of the contact structure and the top of the gate of the semiconductor device is small, which increases the possibility of short circuit between the contact structure and the gate.

### SUMMARY OF THE INVENTION

An object of the invention is to overcome at least one of the above drawbacks and provide an improved semiconductor device and a method for manufacturing the same.

According to an aspect of the invention, there is provided a semiconductor device comprising a gate stack, a source region, a drain region, a contact plug and an interlayer dielectric, the gate stack being formed on a substrate, the source region and the drain region being located on opposite sides of the gate stack and embedded in the substrate, the contact plug being embedded in the interlayer dielectric, wherein the contact plug comprises a first portion which is in contact with the source region and/or drain region, the upper surface of the first portion is flushed with the upper surface of the gate stack, and the angle between a sidewall and a bottom surface of the first portion is less than 90°.

The angle between the sidewall and the bottom surface of the first portion is less than 90°, which can make the top of the first portion less than its bottom. In other words, in the semiconductor device comprising the first portion the top area of the first portion is smaller and its bottom area is larger, as compared with other semiconductor devices of the same size. Therefore, not only the contact area between the first portion and the source region and/or the drain region can be increased, which facilitates reducing the contact resistance; but also the distance between the top of the first portion and the top of the gate stack can be increased, which facilitates reducing the possibility of short circuit between the first portion and the gate stack.

According to another aspect of the invention, there is provided a method for manufacturing a semiconductor device, comprising:

forming a gate stack base on a (100) substrate, and forming a source region and a drain region on opposite sides of the gate stack base;

forming an epitaxial layer on the source region and/or the drain region by faceted epitaxial growth, so that the angle between a sidewall and a bottom surface of the epitaxial layer is less than 90°;

forming planarized interlayer dielectric to expose the epitaxial layer;

removing at least a part of the epitaxial layer to form a contact hole; and

filling the contact hole with a conductive material.

By firstly forming the epitaxial layer by faceted epitaxial growth on the source region and/or drain region formed on the (100) substrate to make the angle between the sidewall of the epitaxial layer and its bottom surface less than 90°, then forming the contact hole after removing at least a part of the epitaxial layer and then filling the contact hole with a conductive material so that the first portion can be formed, the angle between the sidewall of the first portion and its bottom surface is made to be less than 90°, namely, the top of the first portion is made to be less than its bottom. In other words, in the semiconductor device comprising the first portion the top area of the first portion is smaller and its bottom area is larger, as compared with other semiconductor devices of the same size. Therefore, not only the contact area between the first portion and the source region and/or the drain region can be increased, which facilitates reducing the contact resistance; but also the distance between the top of the first portion and the top of the gate stack can be increased, which facilitates reducing the possibility of short circuit between the first portion and the gate stack.

### BRIEF DESCRIPTION OF THE DRAWINGS

These and other objects, features and advantages of the invention will become more apparent from the following detailed description of the exemplary embodiments of the invention with reference to the accompanying drawings. In the drawings:

FIG. 1 shows a schematic cross section view of a prior contact structure;

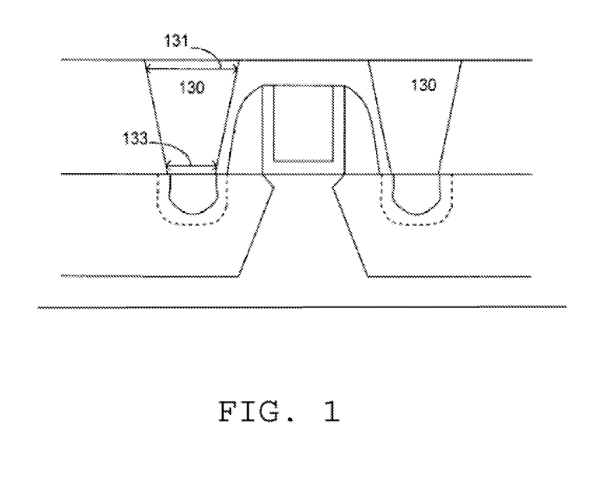

FIG. 2 shows a schematic cross section view of a semiconductor device according to an exemplary embodiment of the invention;

FIG. 3A shows the first step of a method for manufacturing a semiconductor device according to an exemplary embodiment of the invention, through which an epitaxial layer is formed;

FIG. 3B shows the second step of a method for manufacturing a semiconductor device according to an exemplary embodiment of the invention, in which an interlayer dielectric is formed;

FIG. 3C shows the third step of a method for manufacturing a semiconductor device according to an exemplary embodiment of the invention, through which a planarized interlayer dielectric is formed;

FIG. 3D shows the fourth step of a method for manufacturing a semiconductor device according to an exemplary embodiment of the invention, in which a contact hole is formed;

FIG. 3E shows the fifth step of a method for manufacturing a semiconductor device according to an exemplary embodiment of the invention, through which a contact layer is formed;

FIG. 3F shows the sixth step of a method for manufacturing a semiconductor device according to an exemplary embodiment of the invention, in which a conductive material is used for filling the contact hole;

FIG. 3G shows the seventh step of a method for manufacturing a semiconductor device according to an exemplary embodiment of the invention, in which a planarized first portion is formed.

### DETAILED DESCRIPTION OF THE INVENTION

Exemplary embodiments of the invention will be described in detail with reference to the accompanying drawings hereinafter. The drawings are schematic and not drawn to scale, and just for illustrating the embodiments of the invention and are not intended to limit the protective scope of the invention. For making the technical solution of the invention clearer, process steps and structures of a device known in the art are omitted herein.

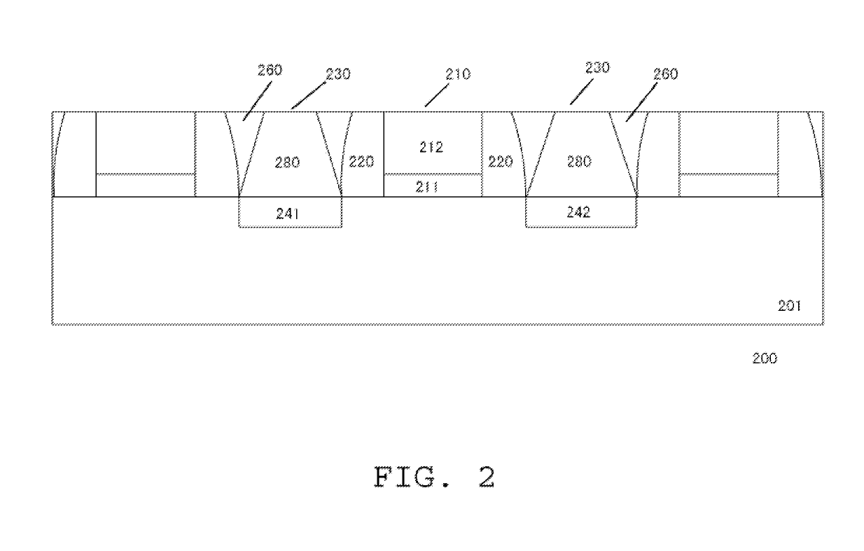

Firstly, a semiconductor device according to an exemplary embodiment of the invention will be described in detail with reference to FIG. 2.

As shown in FIG. 2, a first portion 280 of a contact plug 230 according to an exemplary embodiment of the invention is formed on a source region 241 and/or a drain region 242 of the semiconductor device. While it is illustrated in FIG. 2 that the first portion 280 is formed on both the source region 241 and the drain region 242 of the semiconductor device, the first portion 280 may also be formed on only one of the source region 241 and the drain region 242 as desired, just as known by those skilled in the art.

As an example, the material of the first portion 280 may be a first metal material (i.e., a metal layer). The first metal material may comprise, but not limited to, one or any combination of materials selected from a group of the following materials: W, Al, TiAl, Cu. Optionally, a liner (i.e., a blocking layer, not shown) can be disposed outside the first portion 280. In an example, the liner is formed from a second metal material. The second metal material may comprise, but not limited to, one or any combination of materials selected from a group of the following materials: Ti, TiN, Ta, TaN or Ru.

The top area of the first portion 280 is smaller than its bottom area. Since the bottom area of the first portion 280 is large, this facilitates reducing the contact resistance between the first portion 280 and the source region 241 and the drain region 242 of the semiconductor device. In the exemplary embodiment as shown in FIG. 2, the upper surface of the first portion 280 is flushed with the upper surface of a gate stack 210 (Herein, the term “flushed” means the height difference between the two surfaces is within the error range allowed by the process), and the angle between the sidewall of the first portion 280 and its bottom surface is less than 90°. In particular, the angle between the sidewall and the bottom surface of the first portion 280 may be in the range of 50°-60°.

As shown in FIG. 2, the semiconductor device 200 according to an exemplary embodiment of the invention comprises: a substrate 201; the gate stack 210 formed on the substrate 201; the source region 241 and the drain region 242 located in the substrate on opposite sides of the gate stack 210 respectively; the first portions 280 of the contact plugs 230 formed on at least one of the source region 241 and the drain region 242; and interlayer dielectrics 260 with the contact plugs 230 embedded therein.

The substrate 201 may be silicon or germanium, or may further be silicon-on-insulator (SOI) or silicon-germanium-on-insulator, or may also be any semiconductor material formed on the semiconductor substrate such as SiC, etc., or may even be III-V compound semiconductor (e.g., GaAs, InP, etc.) or II-VI compound semiconductor (e.g., ZnSe, ZnS), or the like.

The gate stack 210 may comprise a gate dielectric 211 and a gate electrode 212 located on the gate dielectric 211. In this embodiment, the gate stack 210 further comprises a spacer isolating layer 220 (the spacer isolating layer may be a single layer or multilayer structure; when the spacer isolating layer is a multilayer structure, the materials between adjacent layers may be different; in other embodiments, the spacer isolating layer may not be included), which is disposed on the sidewalls of the gate dielectric 211 and the gate electrode 212. As an example, the gate dielectric 211 may be formed from silicon oxide, silicon oxynitride or a high-k dielectric material (for example, one of HfO₂, HfSiO, HfSiON, HfTaO, HfSiO, HfZrO, Al2O₃, La₂O₃, ZrO₂, LaAlO or any combination thereof), and the gate electrode 212 may be formed from a conductive material (e.g., a metal or doped semiconductor material such as doped polysilicon).

The source region 241 and the drain region 242 may be formed via the process of ion implantation (where doped particles are implanted into the substrate 201) or by first forming a trench on opposite sides of the gate stack 210 and then epitaxially growing a semiconductor material on the exposed substrate 210, which will not be described in detail. The material of the interlayer dielectric 260 may be doped or undoped silicon oxide glass, such as one of SiOF, SiCOH, SiO, SiCO, SiCON, SiON, PSG (phosphorosilicate glass) or BPSG (boronphosphorosilicate glass) or any combination thereof.

The angle between the sidewall and the bottom surface of the first portion 280 is less than 90°, which makes the top of the first portion 280 less than its bottom. In other words, in the semiconductor device comprising the first portion 280 the top area of the first portion 280 is smaller and its bottom area is larger, as compared with other semiconductor devices of the same size. Therefore, not only the contact area between the first portion 280 and the source region 241 and/or the drain region 242 can be increased, which facilitates reducing the contact resistance; but also the distance between the top of the first portion 280 and the top of the gate stack 210 can be increased, which facilitates reducing the possibility of short circuit between the first portion 280 and the gate stack 210.

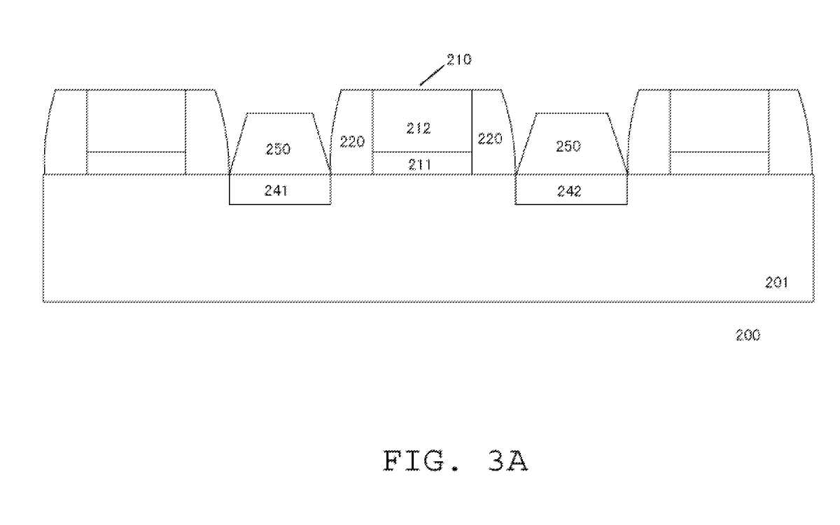

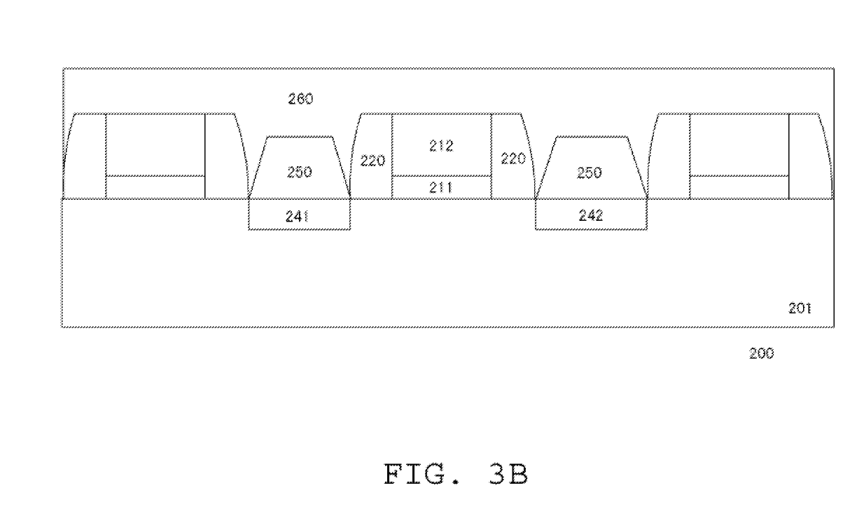

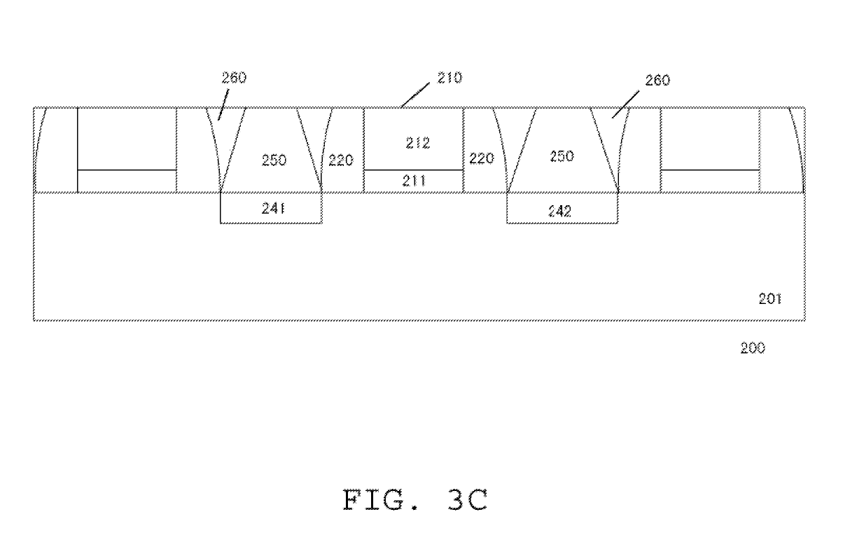

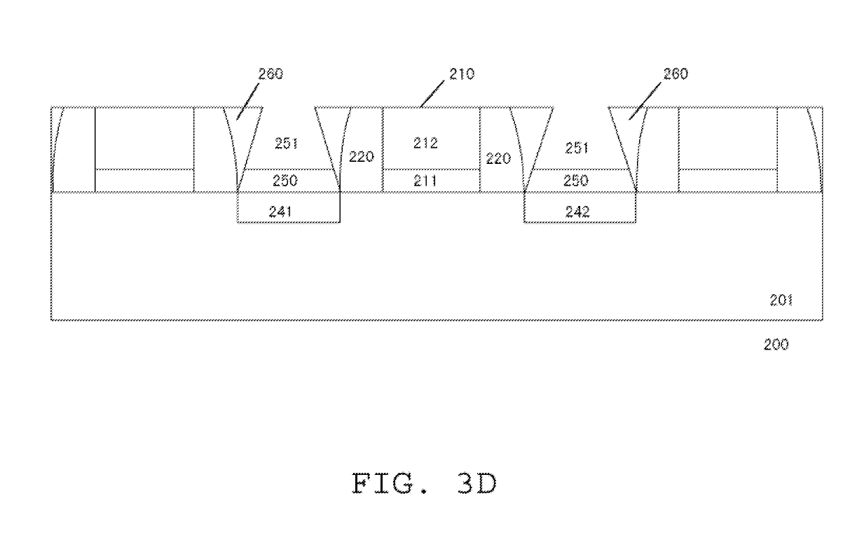

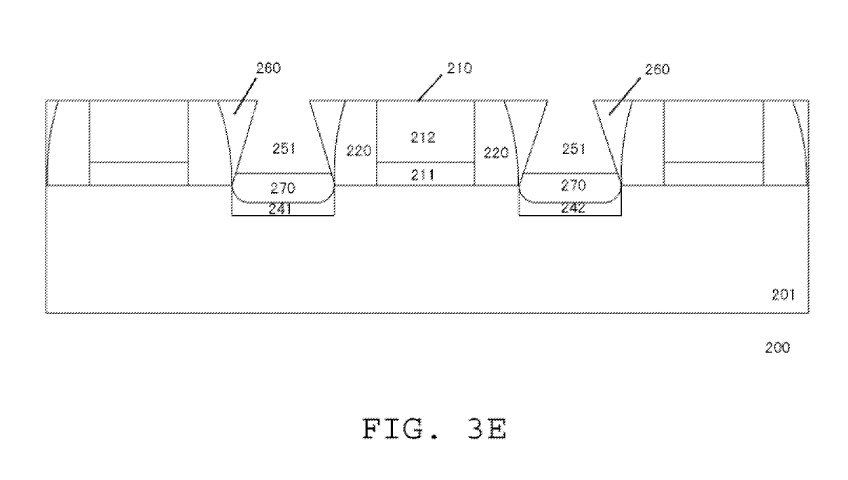

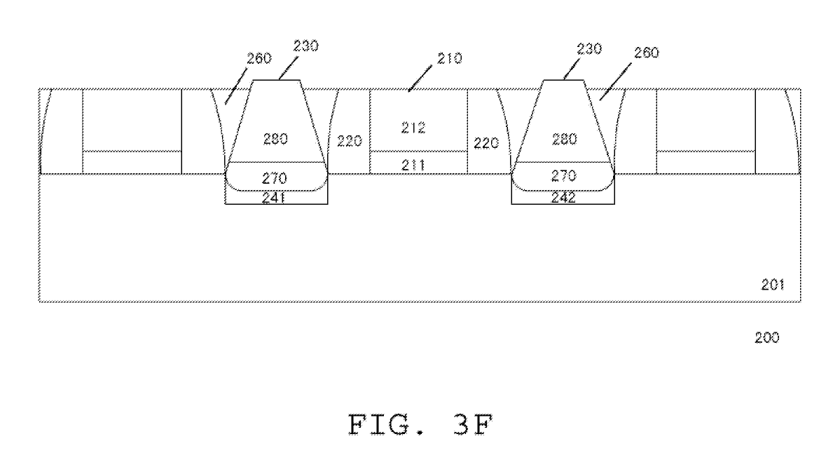

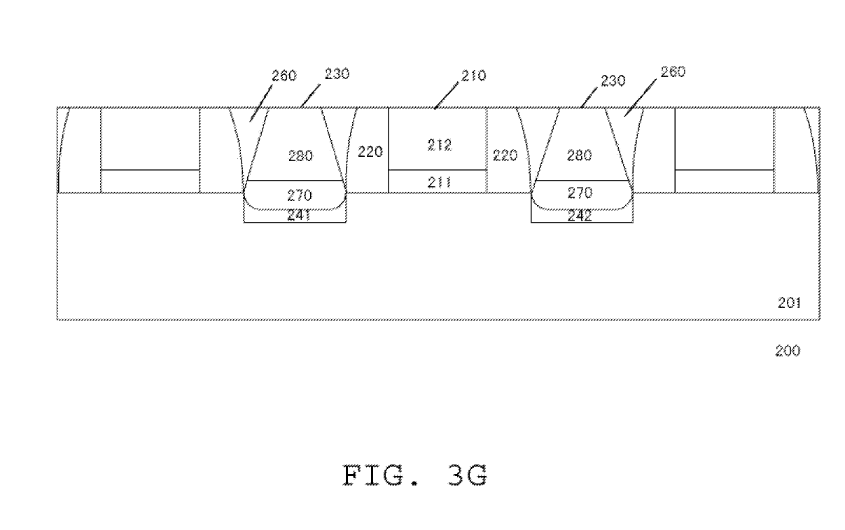

In the following, a method for manufacturing a semiconductor device according to an exemplary embodiment of the invention will be described in detail with reference to FIGS. 3A-3G.

FIG. 3A shows the first step of a method for manufacturing a semiconductor device according to an exemplary embodiment of the invention. An epitaxial layer is formed through this step. More particularly, as shown in FIG. 3A, a gate stack base is formed on a (100) substrate, a source region 241 and a drain region 242 are formed on opposite sides of the gate stack base, and an epitaxial layer 250 is formed on the source region and the drain region by faceted epitaxial growth, so that the angle between a sidewall and a bottom surface of the epitaxial layer 250 is less than 90°.

In this embodiment, the height of the epitaxial layer 250 is less than that of the gate stack base; the respective components of the gate stack base are the same as those of the gate stack 210 as described above, except that the height is different. The gate stack base becomes the gate stack 210 after a subsequent planarization to expose the epitaxial layer 250 and an optional gate replacement process.

As for the faceted epitaxial growth, it means that when a semiconductor material is epitaxially grown on the substrate, the growth rate of the semiconductor material is different in different directions. Taking the substrate material being (100) silicon as an example, when a semiconductor material is epitaxially grown thereon, the growth rate of the semiconductor material on (100) is faster, but the growth rate is slower on (111), which will cause the epitaxial layer in the structure as shown in FIG. 3 to have an inverted cone shaped structure naturally.

As an example, when the substrate is silicon, the material of the epitaxial layer 250 is one of SiGe, Ge, SiC, doped or undoped monocrystalline silicon or polysilicon, or any combination thereof. The epitaxial layer 250 may be a single layer or multiple layers (here the materials of two adjacent layers are different).

FIG. 3B shows the second step of a method for manufacturing a semiconductor device according to an exemplary embodiment of the invention. In this step, an interlayer dielectric 260 is formed. More particularly, the interlayer dielectric 260 formed covers the epitaxial layer 250 and the gate stack base.

FIG. 3C shows the third step of a method for manufacturing a semiconductor device according to an exemplary embodiment of the invention. A planarized interlayer dielectric 260 is formed through this step. More particularly, the epitaxial layer 250 is exposed after planarizing the interlayer dielectric 260. As an example, the process of chemical mechanical polishing (CMP) may be used for planarizing the interlayer dielectric 260.

FIG. 3D shows the fourth step of a method for manufacturing a semiconductor device according to an exemplary embodiment of the invention. In this step, a contact hole is formed. More particularly, at least a part of the epitaxial layer 250 is removed to form the contact hole 251. FIG. 3D illustrates a situation where the epitaxial layer 250 is partially removed. In other embodiments, the epitaxial layer 250 may also be completely removed. Those skilled in the art can make a flexible selection according to the requirements of the process. In an example, the removal of at least a part of the epitaxial layer is performed by a selective etching. If the epitaxial layer comprises a first layer (e.g., Si) and a second layer (e.g., SiGe) and the second layer is formed on the first layer, the step of removing at least a part of the epitaxial layer comprises removing the second layer.

FIG. 3E shows the fifth step of a method for manufacturing a semiconductor device according to an exemplary embodiment of the invention, through which a contact layer 270 is formed. As an example, the contact layer 270 may be formed by the following steps: firstly forming a metal material to cover the bottom surface and the sidewall of the contact hole 251, which metal material may for example be a metal material containing Ni, Co or Ti; then performing the process of annealing to form the contact layer 270 (e.g., metal silicide, such as NiSi, CoSi or TiSi); and finally removing the un-reacted metal material.

FIG. 3F shows the sixth step of a method for manufacturing a semiconductor device according to an exemplary embodiment of the invention. In this step, a conductive material is used for filling the contact hole 251 so as to form the first portion 280 of the contact plug 230. The top area of the first portion 280 is less than its bottom area. The step of filling the contact hole with a conductive material comprises: forming a blocking layer which covers the sidewall and the bottom surface of the contact hole, wherein the blocking layer comprises one of Ta, TaN, Ti, TiN and Ru, or any combination thereof; and then forming a metal layer on the blocking layer, wherein the metal layer comprises one of W, Al, Cu, TiAl, or any combination thereof.

FIG. 3G shows the seventh step of a method for manufacturing a semiconductor device according to an exemplary embodiment of the invention. In this step, the first portion 280 is planarized. As an example, the process of chemical mechanical polishing (CMP) may be used for planarizing the first portion 280.

By firstly forming the epitaxial layer by faceted epitaxial growth on the source region and/or drain region formed on the (100) substrate to make the angle between the sidewall of the epitaxial layer and its bottom surface less than 90°, then forming the contact hole after removing at least a part of the epitaxial layer and then filling the contact hole with a conductive material so that the first portion can be formed, the angle between the sidewall of the first portion and its bottom surface is made to be less than 90°, namely, the top of the first top is made to be less than its bottom. In other words, in the semiconductor device comprising the first portion the top area of the first portion is smaller and its bottom area is larger, as compared with other semiconductor devices of the same size. Therefore, not only the contact area between the first portion and the source region and/or the drain region can be increased, which facilitates reducing the contact resistance; but also the distance between the top of the first portion and the top of the gate stack can be increased, which facilitates reducing the possibility of short circuit between the first portion and the gate stack.

While the exemplary embodiments of the invention have been described in detail with reference to the drawings, such a description is to be considered illustrative or exemplary and not restrictive; the invention is not limited to the disclosed embodiments. Various embodiments described in the above and the claims may also be combined. Other variations to the disclosed embodiments can be understood and effected by those skilled in the art in practicing the claimed invention, from a study of the drawings, the disclosure, and the appended claims, which variations also fall within the protective scope of the invention.

In the claims, the word “comprising” does not exclude the presence of other elements or steps, and “a” or “an” does not exclude a plurality. The mere fact that certain measures are recited in mutually different dependent claims does not indicate that a combination of these measures cannot be used to advantage.

1. A semiconductor device comprising a gate stack, a source region, a drain region, a contact plug and an interlayer dielectric, the gate stack being formed on a substrate, the source region and the drain region being located on opposite sides of the gate stack and embedded in the substrate, the contact plug being embedded in the interlayer dielectric, wherein the contact plug comprises a first portion which is in contact with the source region and/or drain region, the upper surface of the first portion is flushed with the upper surface of the gate stack, and the angle between a sidewall and a bottom surface of the first portion is less than 90°.

2. The semiconductor device as claimed in claim 1, wherein the angle between the sidewall and the bottom surface of the first portion is in the range of about 50°-60°.

3. The semiconductor device as claimed in claim 1, wherein the first portion comprises:
a blocking layer, which is connected with the source region and/or the drain region as well as the interlayer dielectric and the material of which is one of Ta, TaN, Ti, TiN and Ru or any combination thereof; and
a metal layer, which is sandwiched in the blocking layer and is made of one of W, Al, Cu and TiAl, or any combination thereof.

4. A method for manufacturing a semiconductor device comprising:
forming a gate stack base on a (100) substrate, and forming a source region and a drain region on opposite sides of the gate stack base;
forming an epitaxial layer on the source region and/or the drain region by faceted epitaxial growth, so that the angle between a sidewall and a bottom surface the epitaxial layer is less than 90°;
forming planarized interlayer dielectric to expose the epitaxial layer;
removing at least a part of the epitaxial layer to form a contact hole; and
filling the contact hole with a conductive material.

5. The method as claimed in claim 4, wherein the height of the epitaxial layer is less than the height of the gate stack base.

6. The method as claimed in claim 4, wherein when the substrate is silicon, the material of the epitaxial layer is one of SiGe, Ge, SiC, doped or undoped monocrystalline silicon and polysilicon, or any combination thereof.

7. The method as claimed in claim 6, wherein the epitaxial layer comprises at least two layers, and the materials of two adjacent layers are different.

8. The method as claimed in claim 7, wherein when the epitaxial layer comprises a first layer and a second layer formed on the first layer, the step of removing at least a part of the epitaxial layer comprises removing the second layer.

9. The method as claimed in claim 4, wherein between the steps of forming a contact hole and filling the contact hole further comprises forming a contact layer on the epitaxial layer or on the substrate exposed by the contact hole.

10. The method as claimed in claim 4, wherein the step of filling the contact hole with a conductive material comprises:
forming a blocking layer which covers the sidewall and the bottom surface of the contact hole, wherein the blocking layer comprises one of Ta, TaN, Ti, TiN and Ru, or any combination thereof; and
forming a metal layer on the blocking layer, wherein the metal layer comprises one of W, Al, Cu, and TiAl, or any combination thereof.
